(19) United States
(12) Patent Application Publication
(10) Pub. No.: US 2020/0130124 A1
(43) Pub. Date: Apr. 30, 2020

(54) GRINDING APPARATUS, GRINDING METHOD AND COMPUTER-READABLE RECORDING MEDIUM

(71) Applicant: Tokyo Electron Limited, Toyo (JP)

(72) Inventors: Takeshi TAMURA, Koshi City, Kumamoto (JP); Munehisa KODAMA, Koshi City, Kumamoto (JP)

(21) Appl. No.: 16/629,976

(22) PCT Filed: Jul. 3, 2018
(86) PCT No.: PCT/JP2018/025158

§ 371 Date: Jan. 10, 2020

(30) Foreign Application Priority Data
Jul. 12, 2017 (JP) 2017-136026

(51) Int. Cl. B24B 7/22; H01L 21/304; H01L 21/66

(52) U.S. Cl. CPC B24B 7/228; H01L 22/26; H01L 21/304

(57) ABSTRACT

A grinding apparatus configured to grind a substrate includes a substrate holder configured to hold the substrate; and an annular grinder configured to come into contact with at least a central portion and a peripheral portion of the substrate held by the substrate holder to grind the substrate. The substrate holder includes multiple substrate holders and the grinder includes multiple grinders. A diameter of at least one of the multiple grinders is different from a diameter of others of the multiple grinders.

### TECHNICAL FIELD

### Cross-Reference to Related Application

This application claims the benefit of Japanese Patent Application No. 2017-136026 filed on Jul. 12, 2017, the entire disclosures of which are incorporated herein by reference.

The various aspects and embodiments described herein pertain generally to a grinding apparatus configured to grind a substrate, a grinding method using the grinding apparatus, and a computer-readable recording medium.

### BACKGROUND

Recently, in a manufacturing process for a semiconductor device, a semiconductor wafer (hereinafter, simply referred to as “wafer”) having, for example, a plurality of electronic circuits formed on a front surface thereof is thinned by grinding a rear surface of the wafer.

The grinding of the rear surface of the wafer is performed in a grinding apparatus which is equipped with a chuck configured to rotate the wafer by holding, for example, the front surface of the wafer; and an annular grinding wheel configured to be rotatable and having a grinding whetstone configured to grind the rear surface of the wafer held by the chuck. In this grinding apparatus, by pressing the grinding whetstone onto the rear surface of the wafer while rotating the chuck (wafer) and the grinding wheel (grinding whetstone), the rear surface of the wafer is ground.

If the rear surface of the wafer is ground by using the annular grinding wheel, a grinding mark (saw mark) is formed on the rear surface of the wafer in a radial shape from a central portion of rear surface toward a periphery thereof. To be more specific, the saw mark is formed due to constant rotation speeds of the chuck and the grinding wheel. If the wafer is ground by rotating the grinding wheel at a preset rotation speed while rotating the chuck at a predetermined rotation speed, a unique saw mark is formed on a ground surface of the wafer. Since this saw mark reduces a flexural strength of devices obtained by dicing the wafer, a countermeasure to this saw mark is required.

In this regard, Patent Document 1, for example, proposes regularly or randomly varying at least one of the rotation speed of the grinding wheel and the rotation speed of the chuck holding the wafer during the grinding of the wafer grinding. In such a case, correlation between the grinding wheel and the chuck due to the constant rotation speeds thereof can be weakened. Thus, it is attempted to reduce the saw mark formed on the ground surface of the wafer by performing the grinding of the wafer such that the saw mark formed on the ground surface of the wafer is removed because of the varying rotation speed.

### PRIOR ART DOCUMENT

Patent Document 1: Japanese Patent Laid-open Publication No. 2008-047697

### DISCLOSURE OF THE INVENTION

### Problems to be Solved by the Invention

However, by the method described in Patent Document 1, that is, by the method of varying the rotation speed of at least one of the grinding wheel and the chuck, the saw mark cannot be removed sufficiently. Furthermore, as it is not easy to vary the rotation speeds of the grinding wheel and the chuck during the grinding of the wafer, a control over the rotations of the grinding wheel and the chuck becomes very complicated. Therefore, the rotation speed(s) may not be varied at an appropriate timing. From this point of view as well, the saw mark cannot be reduced sufficiently. Since the saw mark remains on the rear surface of the wafer for these reasons, the flexural strength of the diced devices is reduced.

In view of the foregoing, exemplary embodiments provide a technique of improving a flexural strength of a substrate by appropriately grinding a rear surface of the substrate.

### Means for Solving the Problems

The present inventors have conducted researches and found out that a flexural strength of the substrate is reduced if a saw mark formed by rough grinding and a saw mark formed by fine grinding are of a same shape and are formed while being overlapped with each other in a grinding processing in which the rough grinding and the fine grinding are consecutively performed on the substrate, for example. That is, if a shape of a contact portion in which an annular grinding wheel (grinder) used in the rough grinding comes into contact with the substrate and a shape of a contact portion in which an annular grinding wheel used in the fine grinding comes into contact with the substrate are of a same shape, the flexural strength of the substrate is reduced.

In one exemplary embodiment, a grinding apparatus configured to grind a substrate includes a substrate holder configured to hold the substrate; and an annular grinder configured to come into contact with at least a central portion and a peripheral portion of the substrate held by the substrate holder to grind the substrate. The substrate holder includes multiple substrate holders and the grinder includes multiple grinders. A diameter of at least one of the multiple grinders is different from a diameter of others of the multiple grinders.

According to the present exemplary embodiment, since the diameter of the one of the multiple grinders is different from the diameter of the other grinders, a shape of a contact portion of the one grinder which comes into contact with the substrate can be made to be different from a contact portion of the other grinders which comes into contact with the substrate. Accordingly, a saw mark formed by this one grinder and a saw mark formed by the other grinders have different shapes, so that a flexural strength of the substrate can be improved.

In another exemplary embodiment, a grinding method of grinding a substrate includes multiple grinding processes of grinding the substrate by bringing an annular grinder into contact with at least a central portion and a peripheral portion of the substrate held by a substrate holder. The grinder includes multiple grinders, and a diameter of at least one of the multiple grinders used in the multiple grinding processes is different from a diameter of others of the multiple grinders.

In still another exemplary embodiment, there is provided a computer-readable recording medium having stored thereon computer-executable instructions that, in response to execution, cause a grinding apparatus to perform a grinding method.

### Effect of the Invention

According to the exemplary embodiments, it is possible to improve a flexural strength of a substrate by grinding a rear surface of the substrate appropriately.

### BRIEF DESCRIPTION OF THE DRAWINGS

FIG. 1 is a plan view schematically illustrating a configuration of a substrate processing system equipped with a grinding apparatus according to an exemplary embodiment.

FIG. 2 is a side view schematically illustrating a chuck and a rotating mechanism.

FIG. 3 is a side view schematically illustrating a configuration of the grinding apparatus.

FIG. 4 is a plan view schematically illustrating the configuration of the grinding apparatus.

FIG. 5A to FIG. 5C are explanatory diagrams schematically illustrating a grinding processing performed in the grinding apparatus: FIG. 5A illustrates a state where rough grinding is performed;

FIG. 5B, a state where medium grinding is performed; and FIG. 5C, a state where fine grinding is performed.

FIG. 6A to FIG. 6C are explanatory diagrams illustrating a saw mark formed on a rear surface of a wafer: FIG. 6A illustrates a saw mark formed by rough grinding and medium grinding;

FIG. 6B, a saw mark formed by fine grinding; and FIG. 6C, both the saw marks of FIG. 6A and FIG. 6B.

FIG. 7 is a plan view schematically illustrating a configuration of a grinding apparatus according to another exemplary embodiment.

FIG. 8 is a plan view schematically illustrating a configuration of a grinding apparatus according to still another exemplary embodiment.

FIG. 9A to FIG. 9C are explanatory diagrams schematically illustrating a grinding processing performed in the grinding apparatus according to the still another exemplary embodiment: FIG. 9A illustrates a state where rough grinding is performed; FIG. 9B, a state where fine grinding is performed; and FIG. 9C, a state where polishing is performed.

FIG. 10 is a plan view schematically illustrating a configuration of a grinding apparatus according to yet another exemplary embodiment.

FIG. 11 is a side view schematically illustrating a chuck, a rotating mechanism and a rough grinding unit according to still another exemplary embodiment.

FIG. 12 is an explanatory diagram illustrating a state where rough grinding is performed in the rough grinding unit.

FIG. 13 is an explanatory diagram illustrating a state where rough grinding is performed by using a rough grinding wheel.

### DETAILED DESCRIPTION

Hereinafter, exemplary embodiments will be described with reference to the accompanying drawings. In the specification and the drawings, parts having substantially same functions and configurations will be assigned same reference numerals, and redundant description thereof will be omitted.

<Substrate Processing System>

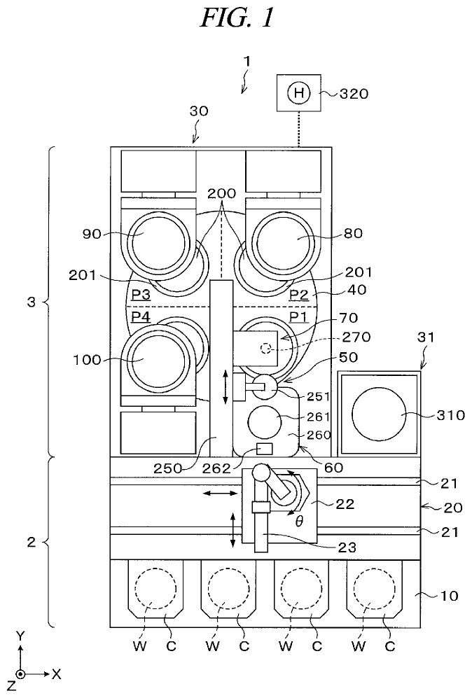

First, a configuration of a substrate processing system equipped with a grinding apparatus according to an exemplary embodiment will be described. FIG. 1 is a plan view schematically illustrating a configuration of a substrate processing system 1. In the following, in order to clarify positional relationships, the X-axis, Y-axis and Z-axis which are orthogonal to each other will be defined. The positive Z-axis direction will be regarded as a vertically upward direction.

In the substrate processing system 1 according to the present exemplary embodiment, a wafer W as a substrate is thinned. The wafer W is a semiconductor wafer such as, but not limited to, a silicon wafer or a compound semiconductor wafer. An electronic circuit (not shown) is formed on a front surface of the wafer W, and a protective tape (not shown) for protecting the electronic circuit is attached on the front surface. The wafer is thinned as a preset processing such as grinding is performed on a rear surface of the wafer W.

The substrate processing system 1 includes a carry-in/out station 2 and a processing station 3 connected as a single body. The carry-in/out station 2 is configured as a carry-in/out section in which a cassette C, which is capable of accommodating therein a plurality of wafers W, is carried in/out from/to the outside. The processing station 3 is equipped with various kinds of processing apparatuses configured to perform preset processings on the wafer W.

The carry-in/out station 2 is equipped with a cassette placing table 10. In the shown example, the cassette placing table 10 is configured to be capable of holding a plurality of, for example, four cassettes C in series in the X-axis direction.

Further, the carry-in/out station 2 includes a wafer transfer area 20 provided adjacent to the cassette placing table 10. A wafer transfer device 22 configured to be movable on a transfer path 21 extending in the X-axis direction is provided in the wafer transfer area 20. The wafer transfer device 22 is equipped with a transfer arm 23 configured to be movable in the horizontal direction and the vertical direction and pivotable around a horizontal axis and a vertical axis (θ direction), and is capable of transferring, with this transfer arm 23, the wafers W between the cassette C on each cassette placing plate 11 and respective apparatuses 30 and 31 of the processing station 3 to be described later. That is, the carry-in/out station 2 is configured to be capable of carrying the wafers W into/from the processing station 3.

Within the processing station 3, the grinding apparatus 30 configured to perform various processings such as grinding on the wafer W to thin the wafer W and the cleaning apparatus 31 configured to clean the wafer W processed by the grinding apparatus 30 are arranged toward the positive X-axis direction from the negative X-axis direction.

The grinding apparatus 30 includes a turntable 40, a transfer unit 50, an alignment unit 60, a cleaning unit 70, a rough grinding unit 80, a medium grinding unit 90, and a fine grinding unit 100.

(Turntable)

The turntable 40 is configured to be rotated by a rotating device (not shown). Four chucks 200 as substrate holders each configured to attract and hold the wafer W are provided on the turntable 40. The chucks 200 are arranged on a circle concentric with the turntable 40 at a regular distance, that is, an angular distance of 90 degrees therebetween. The four chucks 200 can be moved to four processing positions P1 to P4 as the turntable 40 is rotated.

In the present exemplary embodiment, the first processing position P1 is a position at a positive X-axis and negative Y-axis side of the turntable 40, and the cleaning unit 70 is disposed thereat. Further, the alignment unit 60 is disposed at a negative Y-axis side of the first processing position P1. The second processing position P2 is a position at a positive X-axis and positive Y-axis side of the turntable 40, and the rough grinding unit 80 is disposed thereat. The third processing position P3 is a position at a negative X-axis and positive Y-axis side of the turntable 40, and the medium grinding unit 90 is disposed thereat. The fourth processing position P4 is a position at a negative X-axis and negative Y-axis side of the turntable 40, and the fine grinding unit 100 is disposed thereat.

(Chuck)

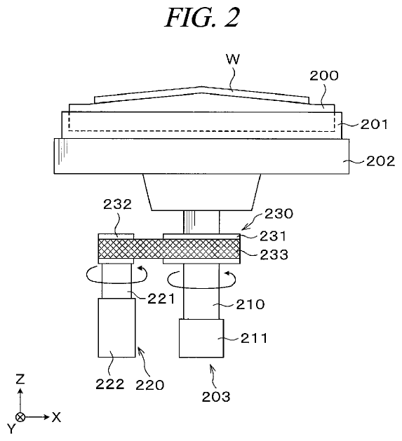

As depicted in FIG. 2, a front surface of each chuck 200, that is, a holding surface for the wafer W has a protruding shape with a central portion protruding higher than an end portion thereof, when viewed from the side. In a grinding processing (rough grinding, medium grinding and fine grinding), a part of a grinding whetstone 281 (291, 301) to be described later comes into contact with the wafer W. The front surface of the chuck 200 is formed to have the protruding shape and the wafer W is attracted to conform to this front surface of the chuck 200 so that the wafer W is ground into a uniform thickness.

By way of example, a porous chuck is used as the chuck 200. The chuck 200 is held on a chuck table 201. The chuck 200 and the chuck table 201 are supported on a base 202. The base 202 is equipped with a rotating device 203 configured to rotate the chuck 200, the chuck table 201 and the base 202. An in-plane inclination of the chuck 200, the chuck table 201 and the base 202 are adjusted by an adjusting device (not shown).

The rotating device 203 is equipped with: a rotation shaft 210 configured to rotate the chuck 200; a driving unit 220 configured to apply a rotational driving force when rotating the chuck 200; and a driving force transmitter 230 configured to transmit the rotational driving force applied by the driving unit 220 to the rotation shaft 210. The rotation shaft 210 is fixed at a central portion of a bottom of the base 202. Further, the rotation shaft 210 is rotatably supported at a supporting table 211. The chuck 200 is rotated around this rotation shaft 210.

The driving unit 220 is provided independently from the rotation shaft 210. The driving unit 220 is equipped with a driving shaft 221; and a motor 222 configured to rotate the driving shaft 221.

The driving force transmitter 230 includes a driven pulley 231 provided at the rotation shaft 210, a driving pulley 232 provided at the driving shaft 221 and a belt 233 wound around the driven pulley 231 and the driving pulley 232. The rotational driving force applied by the driving unit 220 is delivered to the rotation shaft 210 via the driving pulley 232, the belt 233 and the driven pulley 231.

(Transfer Unit)

As illustrated in FIG. 1, the transfer unit 50 is configured to be movable on a transfer path 250 extending in the Y-axis direction. The transfer unit 50 has a transfer arm 251 configured to be movable in the horizontal direction and the vertical direction and pivotable around a vertical axis (θ direction), and is capable of transferring the wafer W between the alignment unit 60 and the chuck 200 at the first processing position P1 with this transfer arm 251.

(Alignment Unit)

The alignment unit 60 is configured to adjust a direction of the wafer W before being processed in the horizontal direction. The alignment unit 60 is equipped with a base 260, a spin chuck 261 configured to hold and rotate the wafer W; and a detector 262 configured to detect a notch of the wafer W. A position of the notch of the wafer W is detected by the detector 262 while the wafer W held by the spin chuck 261 is being rotated, and by adjusting the position of the notch, the direction of the wafer W in the horizontal direction is adjusted.

(Cleaning Unit)

The cleaning unit 70 is configured to clean the rear surface of the wafer W. The cleaning unit 70 is disposed above the chuck 200, and is equipped with a nozzle 270 configured to supply a cleaning liquid, for example, pure water onto the rear surface of the wafer W. The cleaning liquid is supplied from the nozzle 270 while the wafer W held by the chuck 200 is being rotated. The supplied cleaning liquid is diffused on the rear surface of the wafer W, so that the rear surface is cleaned. Further, the cleaning unit 70 may further have a function of cleaning the chuck 200. In such a case, the cleaning unit 70 may be equipped with, for example, a nozzle (not shown) configured to supply the cleaning liquid to the chuck 200 and a stone (not shown) configured to come into contact with the chuck 200 and clean the chuck 200 physically.

(Rough Grinding Unit)

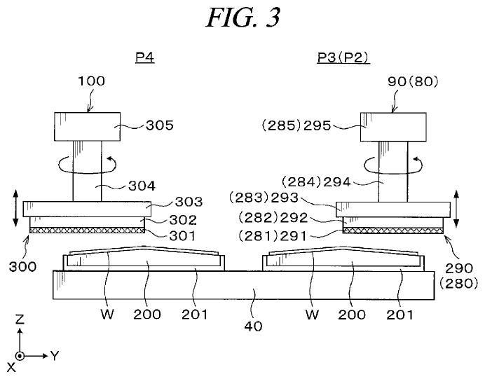

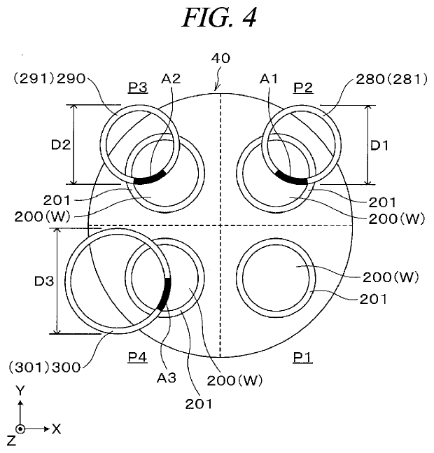

The rough grinding unit 80 is configured to grind the rear surface of the wafer W roughly. As depicted in FIG. 3 and FIG. 4, the rough grinding unit 80 includes a rough grinding wheel 280 as a rough grinder. The rough grinding wheel 280 has an annular shape having an outer diameter D1. Further, the rough grinding wheel 280 has a rough grinding whetstone 281 and a wheel base 282 configured to support the rough grinding whetstone 281. The rough grinding whetstone 281 has the substantially same annular shape as that of the rough grinding wheel 280, and an outer diameter of the rough grinding whetstone 281 is also D1. Furthermore, the rough grinding whetstone 281 comes into contact with a contact area A1 (a shaded area in FIG. 4) connecting a central portion and a peripheral portion of the wafer W. The wheel base 282 is supported at a circular plate-shaped mount 283, and the mount 283 is connected to a driver 285 via a spindle 284. The driver 285 incorporates, for example, a motor (not shown), and is configured to move the rough grinding wheel 280 in the vertical direction and rotate it. By respectively rotating the chuck 200 and the rough grinding whetstone 281 while keeping the wafer W held by the chuck 200 in contact with a part (contact area A1) of an arc of the rough grinding whetstone 281, the rear surface of the wafer W is roughly ground. At this time, a grinding liquid, for example, water is supplied onto the rear surface of the wafer W. Further, in the present exemplary embodiment, though the rough grinding whetstone 281 is used as a grinding member for the rough grinding, the grinding member is not limited thereto. By way of non-limiting example, the grinding member may be a non-woven fabric containing abrasive grains, or the like.

(Medium Grinding Unit)

The medium grinding unit 90 is configured to grind the rear surface of the wafer W at a medium level. A configuration of the medium grinding unit 90 is substantially the same as the configuration of the rough grinding unit 80, and the medium girding unit 90 is equipped with a medium grinding wheel 290 as a medium grinder, a medium grinding whetstone 291, a wheel base 292, a mount 293, a spindle 294 and a driver 295. An outer diameter D2 of the medium grinding wheel 290 (medium grinding whetstone 291) is equal to the outer diameter D1 of the rough grinding wheel 280 (rough grinding whetstone 281). Further, the medium grinding whetstone 291 comes into contact with a contact area A2 (a shaded area in FIG. 4) connecting the central portion and the peripheral portion of the wafer W. Furthermore, a particle size of the medium grinding whetstone 291 is smaller than a particle size of the rough grinding whetstone 281. By respectively rotating the chuck 200 and the medium grinding whetstone 291 while supplying the grinding liquid onto the rear surface of the wafer W held by the chuck 200 in the state that the rear surface of the wafer W is in contact with a part (contact area A2) of an arc of the medium grinding whetstone 291, the rear surface of the wafer W is ground.

(Fine Grinding Unit)

The fine grinding unit 100 is configured to grind the rear surface of the wafer W finely. A configuration of the fine grinding unit 100 is substantially the same as the configurations of the rough grinding unit 80 and the medium grinding unit 90, and the fine grinding unit 100 is equipped with a fine grinding wheel 300 as a fine grinder, a fine grinding whetstone 301, a wheel base 302, a mount 303, a spindle 304 and a driver 305. An outer diameter D3 of the fine grinding wheel 300 (fine grinding whetstone 301) is larger than the outer diameter D1 of the rough grinding wheel 280 (rough grinding whetstone 281) and the outer diameter D2 of the medium grinding wheel 290 (medium grinding whetstone 291). Further, the fine grinding whetstone 301 comes into contact with a contact area A3 (a shaded area in FIG. 4) connecting the central portion and the peripheral portion of the wafer W. Furthermore, a particle size of the fine grinding whetstone 301 is smaller than the particle size of the medium grinding whetstone 291. By respectively rotating the chuck 200 and the fine grinding whetstone 301 while supplying the grinding liquid onto the rear surface of the wafer W held by the chuck 200 in the state that the rear surface of the wafer W is in contact with a part (contact area A3) of an arc of the fine grinding whetstone 301, the rear surface of the wafer W is ground.

As stated above, in the grinding apparatus 30, the rear surface of the wafer W is ground in three stages including the rough grinding, the medium grinding and the fine grinding. Further, the outer diameter D1 of the rough grinding wheel 280, the outer diameter D2 of the medium grinding wheel 290 and the outer diameter D3 of the fine grinding wheel 300 are set to satisfy a relationship of D3>D1=D2. By way of example, when the wafer W has a diameter of 300 mm, the outer diameters D1 and D2 are set to be 300 mm and the outer diameter D3 is set to be 400 mm.

(Cleaning Apparatus)

The cleaning apparatus 31 shown in FIG. 1 is configured to clean the rear surface of the wafer W which is ground by the grinding apparatus 30. To elaborate, while rotating the wafer W held by a spin chuck 310, a cleaning liquid, for example, pure water is supplied onto the rear surface of the wafer W. The supplied cleaning liquid is diffused on the rear surface of the wafer W, so that the rear surface is cleaned.

(Controller)

The above-described substrate processing system 1 is equipped with the controller 320 as shown in FIG. 1. The controller 320 is, for example, a computer and includes a program storage (not shown). A program for controlling a processing performed on the wafer W in the substrate processing system 1 is stored in the program storage. Further, the program storage also stores therein a program for implementing a wafer processing to be described later in the substrate processing system 1 by controlling the above-described various processing apparatuses and a driving system such as the transfer devices. Further, the programs may be recorded in a computer-readable recording medium H such as a hard disk (HD), a flexible disk (FD), a compact disk (CD), a magnet optical disk (MO) or a memory card, and may be installed from this recording medium H to the controller 320.

(Wafer Processing)

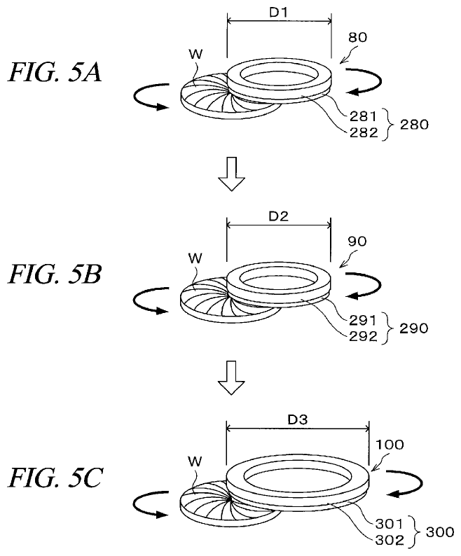

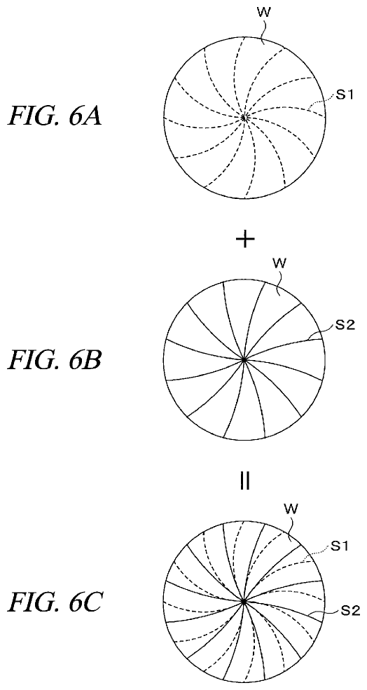

Now, a wafer processing performed by using the substrate processing system 1 having the above-described configuration will be discussed. FIG. 5A to FIG. 5C are explanatory diagrams schematically illustrating a grinding processing performed by the grinding apparatus 30 of the substrate processing system 1. Further, FIG. 6A to FIG. 6C are explanatory diagrams schematically illustrating saw marks formed on the wafer W by the grinding processing in the grinding apparatus 30.

First, a cassette C accommodating therein a plurality of wafers W is placed on the cassette placing table 10 of the carry-in/out station 2. To suppress a deformation of the protective tape, each wafer W is accommodated in the cassette C such that the front surface of the wafer W to which the protective tape is attached faces upwards.

Then, a wafer W is taken out of the cassette C and transferred into the grinding apparatus 30 of the processing station 3 by the wafer transfer device 22. At this time, the front surface and the rear surface of the wafer W are inverted by the transfer arm 23 such that the rear surface of the wafer W faces upwards.

The wafer W transferred into the grinding apparatus 30 is delivered onto the spin chuck 261 of the alignment unit 60. Then, a direction of the wafer W in the horizontal direction is adjusted by the alignment unit 60.

Subsequently, the wafer W is delivered onto the chuck 200 at the first processing position P1 by the transfer unit 50. Thereafter, by rotating the turntable 40 by 90 degrees in the counterclockwise direction, the chuck 200 is moved to the second processing position P2. Then, as illustrated in FIG. 5A, the rear surface of the wafer W is roughly ground by the rough grinding unit 80. A grounding amount by the rough grinding is set based on a thickness of the wafer W before being thinned and a target thickness of the wafer W after being thinned.

Thereafter, the turntable 40 is further rotated by 90 degrees in the counterclockwise direction, and the chuck 200 is moved to the third processing position P3. Then, as depicted in FIG. 5B, the rear surface of the wafer W is ground at a medium level by the medium grinding unit 90. A grinding amount by the medium grinding is also set based on the thickness of the wafer W before being thinned and the target thickness of the wafer W after being thinned.

Thereafter, by further rotating the turntable 40 by 90 degrees in the counterclockwise direction, the chuck 200 is moved to the fourth processing position P4. Then, as illustrated in FIG. 5C, the rear surface of the wafer W is finely ground by the fine grinding unit 100. Here, the wafer W is ground to the thickness after being thinned, which is required as a product.

Here, the saw marks formed on the rear surface of the wafer W by the rough grinding, the medium grinding and the fine grinding will be explained with reference to FIG. 6A to FIG. 6C. As shown in FIG. 6A, saw marks S1 are formed on the rear surface of the wafer W by the rough grinding and the medium grinding. Since the outer diameter D1 of the rough grinding wheel 280 and the outer diameter D2 of the medium grinding wheel 290 are same, the contact area A1 and the contact area A2 for the wafer W are same. Accordingly, the substantially same saw marks S1 are formed in the rough grinding and the medium grinding.

Meanwhile, in the fine grinding, a saw mark S2 is formed on the rear surface of the wafer W, as illustrated in FIG. 6B. Since the outer diameter D3 of the fine grinding wheel 300 is larger than the outer diameter D1 of the rough grinding wheel 280 (the outer diameter D2 of the medium grinding wheel 290), the contact area A3 by the fine grinding wheel 300 is closer to a straight line shape than the contact area A1 by the rough grinding wheel 280 (the contact area A2 by the medium grinding wheel 290). Therefore, the saw mark S2 formed by the fine grinding also becomes closer to a straight line shape than the saw mark S1 formed by the rough grinding and the medium grinding.

As stated above, the saw marks S1 and S2 having the different shapes are formed on the rear surface of the wafer W, as shown in FIG. 6C. Here, in case that the same grinding wheel is used throughout the whole grinding processing including the rough grinding, the medium grinding an the fine grinding as in the prior art described above, saw marks having the same shape are formed on the wafer W, and these saw marks are concentrated on the same portion of the wafer W. As a result, a flexural strength of that portion of the wafer W is reduced. In contrast, in the present exemplary embodiment, portions of the rear surface of the wafer W where the saw marks S1 and S2 are formed are dispersed. Thus, even if the wafer W is divided into devices by dicing the wafer W, a flexural strength of the devices can be improved.

Furthermore, the present inventors have conducted researches and found out that accuracy of the fine grinding, for example, accuracy of the thickness of the wafer W after being finely ground is improved with an increase of the outer diameter D3 of the fine grinding wheel 300. The reason for this is deemed as follows. For example, as a comparative example for the present exemplary embodiment, if the outer diameter D3 is small, the saw mark S2 is diagonally curved as it goes from the central portion of the wafer W toward the peripheral portion thereof. As a result, the accuracy of the fine grinding at the peripheral portion of the wafer W is lowered. In contrast, if the outer diameter D3 is large as in the present exemplary embodiment, the saw mark S2 becomes closers to a straight line shape, and this saw mark S2 becomes a straight line shape at the peripheral portion of the wafer Was well. As a result, the accuracy of the fine grinding is improved. Thus, by setting the outer diameter D3 of the fine grinding wheel 300 to be larger than the outer diameter D1 of the rough grinding wheel 280 (outer diameter D2 of the medium grinding wheel 290), the accuracy of the fine grinding can be ameliorated.

In addition, since the outer diameter D3 of the fine grinding wheel 300 is larger than the outer diameter D1 of the rough grinding wheel 280 (outer diameter D2 of the medium grinding wheel 290), a throughput of the grinding processing can be improved. If the fine grinding wheel 300 is rotated at the same rotation speed, a peripheral speed becomes larger as the outer diameter D3 is larger. Accordingly, a rate at which the fine grinding wheel 300 grounds the rear surface of the wafer W is increased, so that the throughput can be improved. Furthermore, since the peripheral speed is increased, abrasion of the fine grinding whetstone 301 can be suppressed, so that a lifetime of the fine grinding wheel 300 can be improved.

Upon the completion of the rough grinding, the medium grinding and the fine grinding as described above, by further rotating the turntable 40 by 90 degrees in the counterclockwise direction or 270 degrees in the clockwise direction, the chuck 200 is moved to the first processing position P1. Then, the rear surface of the wafer W is cleaned by the cleaning liquid in the cleaning unit 70.

Subsequently, the wafer W is transferred into the cleaning apparatus 31 by the wafer transfer device 22. In the cleaning apparatus 31, the rear surface of the wafer W is cleaned by the cleaning liquid. The cleaning of the rear surface of the wafer W is also performed in the cleaning unit 70 of the processing apparatus 30. In the cleaning unit 70, however, a rotation speed of the wafer W is low, and the cleaning is performed to remove contaminants only to some degree, for example, to the extent that the transfer arm 23 of the wafer transfer device 22 is not contaminated. Meanwhile, in the cleaning apparatus 31, the rear surface of this wafer W is further cleaned to a required degree of cleanness.

Then, the wafer W after being subjected to all the required processings is transferred back into the cassette C on the cassette placing table 10 by the wafer transfer device 22. Then, a series of the wafer processings in the substrate processing system 1 is ended.

According to the present exemplary embodiment as described above, the rough grinding by the rough grinding unit 80, the medium grinding by the medium grinding unit 90, the fine grinding by the fine grinding unit 100 and the cleaning of the rear surface of the wafer W by the cleaning unit 70 and the cleaning apparatus 31 can be performed on the plurality of wafers W consecutively in a single substrate processing system 1. Therefore, the wafer processing can be carried out efficiently within the single substrate processing system 1, so that the throughput can be improved.

Further, according to the present exemplary embodiment, since the saw marks S1 and S2 having the different shapes can be formed on the rear surface of the wafer W in the grinding apparatus 30, the flexural strength of the wafer W and the devices obtained by dicing the wafer W can be improved. Moreover, since the outer diameter D3 of the fine grinding wheel 300 is larger than the outer diameter D1 of the rough grinding wheel 280 (outer diameter D2 of the medium grinding wheel 290), the accuracy of the fine grinding and the throughput of the wafer processing can be improved, and the lifetime of the fine grinding wheel 300 can be lengthened.

<Other Examples of Grinding Apparatus>

Now, other examples of the grinding apparatus 30 will be explained.

### First Modification Example

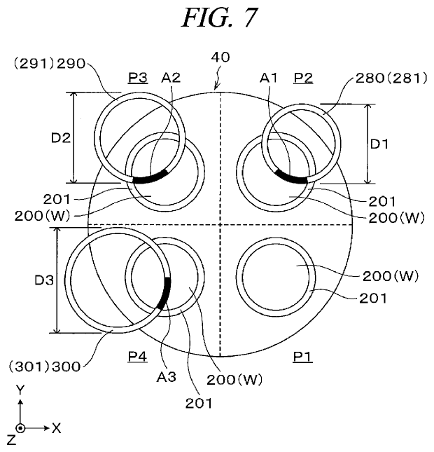

In the above-described exemplary embodiment, the outer diameter D1 of the rough grinding wheel 280, the outer diameter D2 of the medium grinding wheel 290 and the outer diameter D3 of the fine grinding wheel 300 have the relationship of D3>D1=D2. However, the outer diameter D1 of the rough grinding wheel 280, the outer diameter D2 of the medium grinding wheel 290 and the outer diameter D3 of the fine grinding wheel 300 may be all different, as illustrated in FIG. 7. In such a case, since saw marks respectively formed on the rear surface of the wafer W by the rough grinding, the medium grinding and the fine grinding have all different shapes, the flexural strength of the wafer W and the devices can be further improved. Further, if the outer diameters D1, D2 and D3 are set to be all different in this way, it is desirable that they have a relationship of D3>D1>D2.

Here, however, the present inventors have found out that, among the saw marks S1 and S2, the saw mark S2 formed by the fine grinding as a post-process easily remains on the rear surface of the wafer W. Thus, in the aspect of sharing apparatus components for the purpose of reducing equipment cost, the outer diameter D1 of the rough grinding wheel 280 and the outer diameter D2 of the medium grinding wheel 290 may be set to be same.

In addition, to improve the flexural strength, the outer diameter D3 of the fine grinding wheel 300 may be set to be smaller than the outer diameter D1 of the rough grinding wheel 280 (outer diameter D2 of the medium grinding wheel 290), to the contrary to the present exemplary embodiment. However, to improve the accuracy of the fine grinding and the throughput of the wafer processing and increase the lifetime of the fine grinding wheel 300, it is desirable that the outer diameter D3 of the fine grinding wheel 300 is larger than the outer diameter D1 of the rough grinding wheel 280 (the outer diameter D2 of the medium grinding wheel 290) as in the present exemplary embodiment.

### Second Modification Example

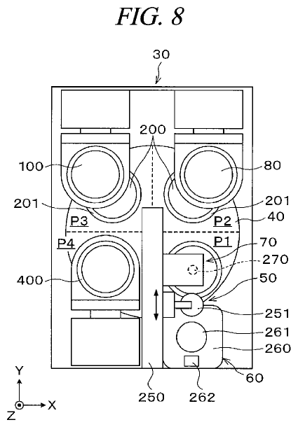

The grinding apparatus 30 according to the above-described exemplary embodiment is equipped with the rough grinding unit 80, the medium grinding unit 90 and the fine grinding unit 100. However, the grinding apparatus 30 may be equipped with the rough grinding unit 80, the fine grinding unit 100 and a polishing unit 400, as illustrated in FIG. 8. The rough grinding unit 80, the fine grinding unit 100 and the polishing unit 400 are placed at the second processing position P2, the third processing position P3 and the fourth processing position P4, respectively.

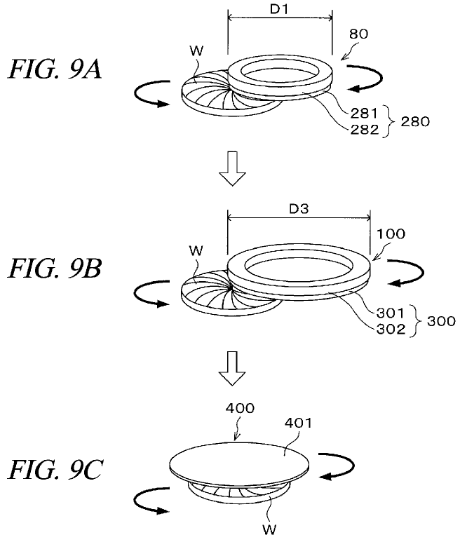

In the polishing unit 400, a gettering layer is formed on the rear surface of the wafer W while removing, through a stress relief processing, a damage layer which is formed on the rear surface of the wafer W when the rough grinding and the fine grinding are performed. In the polishing unit 400, a polishing whetstone 401 comes into contact with the entire rear surface of the wafer W to thereby polish the rear surface of the wafer W, as illustrated in FIG. 9C. Further, though the present exemplary embodiment is described for a case where so-called dry polishing is performed in the polishing unit 400, the exemplary embodiment is not limited thereto. By way of example, the rear surface of the wafer W may be polished while supplying a polishing liquid, for example, water to the rear surface of the wafer W.

In such a case, rough grinding by the rough grinding unit 80 shown in FIG. 9A, fine grinding by the fine grinding unit 100 shown in FIG. 9B and the polishing by the polishing unit 400 shown in FIG. 9C are performed in sequence in the grinding apparatus 30. Further, since the outer diameter D3 of the fine grinding wheel 300 is larger than the outer diameter D1 of the rough grinding wheel 280 in the present example as well, the same effects as described in the above-described exemplary embodiment can be achieved. That is, the flexural strength of the wafer W and the devices can be improved.

<Inspection of Grinding Wheels>

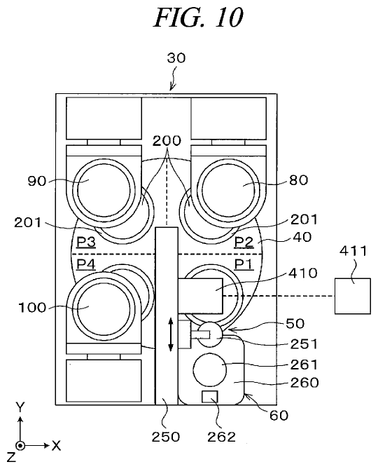

In the above-described grinding apparatus 30, the grinding wheels 280, 290 and 300 may be inspected based on the saw marks S1 and S2. As depicted in FIG. 10, the grinding apparatus 30 is equipped with a detection unit 410 as a detector configured to detect the saw marks S1 and S2 and an inspection unit 411 as an inspector configured to inspect states of the grinding wheels 280, 290 and 300.

The detection unit 410 is placed at, for example, the first processing position P1. The detection unit 410 has, for example, a CCD camera and images the rear surface of the wafer W held by the chuck 200. That is, the saw marks S1 and S2 on the rear surface of the wafer W are detected by the detection unit 410. Images obtained by the detection unit 410 are outputted to the inspection unit 411.

The inspection unit 411 is a part of, for example, the controller 320. In the inspection unit 411, the states of the grinding wheels 280, 290 and 300 are inspected based on the images obtained by the detection unit 410, that is, the saw marks S1 and S2. As shown in FIG. 6A to FIG. 6C, the saw marks S1 and S2 have the different shapes. Accordingly, if the detected saw mark S1 is different from a typical shape, for example, it is determined that either one of the rough grinding wheel 280 and the medium grinding wheel 290 is abnormal. Further, if the detected saw mark S2 is different from a typical shape, it is determined that the fine grinding wheel 300 is abnormal.

In addition, if the outer diameters D1, D2 and D3 of the grinding wheels 280, 290 and 300 are different, the saw marks formed on the rear surface of the wafer W are all different. In such a case, the state of each of the grinding wheels 280, 290 and 300 can be inspected by using the detection unit 410 and the inspection unit 411.

Furthermore, a layout of the detection unit 410 and the inspection unit 411 is not limited to the present exemplary embodiment. By way of example, the detection unit 410 and the inspection unit 411 may be provided at an outside of the grinding apparatus 30 within the substrate processing system 1, or at an outside of the substrate processing system 1. Moreover, a configuration of the detection unit 410 is not limited to the present exemplary embodiment as long as it is capable of detecting the saw marks.

<Air Cut Control>

In the above-described grinding apparatus 30, a so-called air cut amount may be controlled. Since the rough grinding by the rough grinding unit 80, the medium grinding by the medium grinding unit 90 and the fine grinding by the fine grinding unit 100 are substantially the same grinding processings, the following description will be provided only for the rough grinding by the rough grinding unit 80.

In the rough grinding by the rough grinding unit 80, when lowering the rough grinding wheel 280 toward the wafer W, the rough grinding wheel 280 is moved at a high speed to shorten a processing time. If, however, the rough grinding unit 80 is brought into contact with the wafer W at this high speed, the rough grinding unit 80 may be broken or the wafer W may be damaged. Therefore, decelerating the rough grinding unit 80 and moving it at a low speed, that is, a so-called air cut is performed. When this air cut is begun, though the rotation of the rough grinding wheel 280 is begun, the rough grinding wheel 280 is not in contact with the rear surface of the wafer W. As a result, the rough grinding wheel 280 idles, and this is why this operation is called the air cut. The air cut is set in consideration of elastic deformations of the chuck 200, the spindle 284, the rough grinding wheel 280, and so forth.

Here, as a comparative example for the present exemplary embodiment, a conventional method of setting a grinding start position of the grinding whetstone (that is, a start position of the air cut) will be explained. Various methods are used to set the grinding start position conventionally. Japanese Patent Laid-open Publication No. 2016-140922 discloses one example. Specifically, Japanese Patent Laid-open Publication No. 2016-140922 describes a grinding apparatus equipped with an arm extending in a horizontal direction between a chuck and a grinding whetstone; an elevating device configured to move the arm in a vertical direction; and an upper contact sensor provided at a top surface of the arm and configured to detect a contact of the grinding whetstone. In this grinding apparatus, a state where the upper contact sensor is in contact with the grinding whetstone is determined as the grinding start position of the grinding whetstone, and the grinding start position is automatically set in this way.

However, if the grinding whetstone is used to grind multiple wafers, the grinding whetstone is worn away, so that a thickness of the grinding whetstone decreases. That is, a height of a bottom surface of the grinding whetstone of a grinding wheel is changed. In case that the grinding whetstone is worn away, an air cut amount increases if the grinding start position of the grinding whetstone is set to be constant as described in Japanese Patent Laid-open Publication No. 2016-140922. As stated above, the grinding wheel is lowered at the low speed in the air cut. Thus, if the air cut amount is increased, a processing time of the grinding processing is increased, resulting in deterioration of a throughput. In this sense, there is a room for improvement in the conventional method of setting the grinding start position.

In view of the foregoing, in the present exemplary embodiment, to minimize the air cut amount, a load acting on the chuck 200 or the rough grinding wheel 280 at least is measured, and the grinding start position is calculated based on a height position where the load becomes zero.

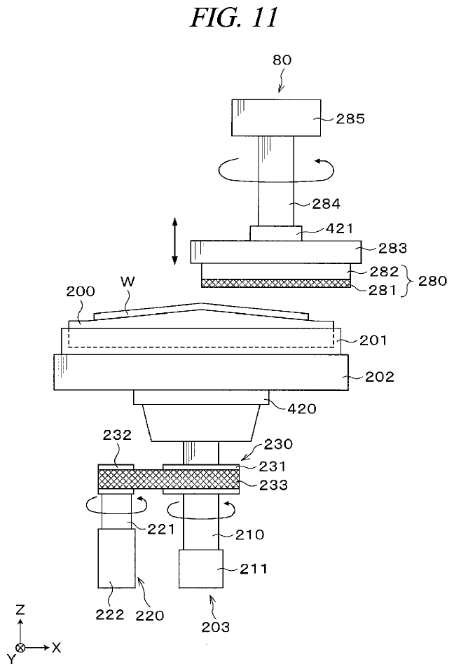

As depicted in FIG. 11, the rough grinding unit 80 has a first load sensor 420 and a second load sensor 421 as a load measurement unit. The first load sensor 420 is configured to measure a load acting on the chuck 200 and is disposed at, for example, a bottom surface of the base 202. The second load sensor 421 is configured to measure a load acting on the rough grinding wheel 280 and is provided at, for example, a top surface of the mount 283. Further, the layout of the load sensors 420 and 421 is not limited to the present exemplary embodiment, and the load sensors 420 and 421 can be disposed at any positions as long as they are capable of measuring the loads acting on the chuck 200 and the rough grinding wheel 280, respectively. Furthermore, the configuration of the load measurement unit is not limited to the present exemplary embodiment, and the load measurement unit may have any of various configurations as long as it is capable of measuring the loads.

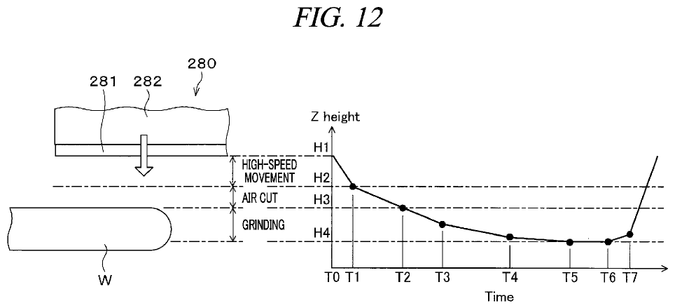

FIG. 12 is an explanatory diagram illustrating a state in which the rough grinding is performed in the rough grinding unit 80. A left drawing of FIG. 12 is an explanatory diagram showing a relationship between the rough grinding wheel 280 and the wafer W in the rough grinding. A right drawing of FIG. 12 is a graph showing a time series variation of a height position of the rough grinding wheel 280 (rough grinding whetstone 281). A vertical axis of this graph indicates a height position of a bottom surface of the rough grinding whetstone 281, and a horizontal axis of the graph represents a time.

First, the rough grinding wheel 280 is lowered from a standby position H1 to a grinding start position H2 at a high speed (from a time T0 to a time T1). Then, the rough grinding wheel 280 is decelerated and moved down at a low speed to a contact position H3 where it comes into contact with the wafer W (from the time T1 to a time T2). The air cut is performed between this grinding start position H2 and the contact position H3. The air cut amount, which is H2-H3, is previously set in consideration of an elastic deformation amount of the rough grinding unit 80.

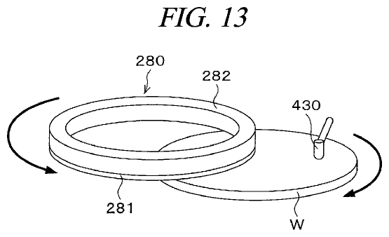

Then, the rough grinding wheel 280 is further lowered, and the rear surface of the wafer W is ground to a grinding end position H4 (from a time T3 to a time T5). From the time T3 to the time T5, as shown in FIG. 13, a height of the rear surface of the wafer W is measured by using, for example, a laser displacement meter 430, and the descent of the rough grinding wheel 280 is stopped at the time (time T5) when the height of the rear surface reaches a preset height where a target thickness of the wafer W is obtained. Further, in the present exemplary embodiment, though the grinding is performed from the time T3 to the time T5 in stages while decelerating the rough grinding wheel 280, the grinding may be performed at a constant speed.

A so-called spark-out state lasts from the time T5 to a time T6. That is, even if the descent of the rough grinding wheel 280 is stopped at the time T5, the rotation of the rough grinding wheel 280 is continued for a certain time ranging from the time T5 to the time T6.

A so-called escape cut state lasts from the time T6 to a time T7. That is, though an ascent of the rough grinding wheel 280 is begun at the time T6, the rotation of the rough grinding wheel 280 is continued for a certain time ranging from the time T6 to the time T7.

Here, the load sensors 420 and 421 measure the loads acting on the chuck 200 and the rough grinding wheel 280, respectively, for a time period ranging from the time T0 to the time T7. Even if the descent of the rough grinding wheel 280 is stopped as the grinding is stopped at the time T5, a load is still applied between the rough grinding wheel 280 and the wafer W. Then, between the time T6 and the time T7, there arise a point where the load becomes zero (hereinafter, referred to as “load zero point”), that is a point where the rough grinding wheel 280 is distanced away from the wafer W. In the present exemplary embodiment, a point where both the load acting on the chuck 200 measured by the first load sensor 420 and the load acting on the rough grinding wheel 280 measured by the second load sensor 421 become zero is set as the load zero point.

A height position of the rough grinding wheel 280 at this load zero point (hereinafter, referred to as “reference position”) is measured. To elaborate, an encoder of the driver 285 is outputted to the controller 320, and the reference position is calculated based on this encoder in the controller 320. Further, in the present exemplary embodiment, the driver 285 and the controller 320 constitute a height measurer of the present disclosure.

In addition, based on this reference position, the controller 320 calculates a grinding start position of the rough grinding wheel 280 for a wafer W to be ground subsequently (hereinafter, referred to as “next wafer W”). To elaborate, the grinding start position is calculated by adding an edge cut amount and a target grinding amount of the next wafer W to the reference position. Then, the rough grinding wheel 280 is feed-forward controlled based on the calculated grinding start position, and rough grinding is then performed on the next wafer W by the rough grinding wheel 280. Further, if a thickness of the wafer W currently being ground (hereinafter, referred to as “current wafer W”) and a thickness of the next wafer W are different, the grinding start position is calculated in consideration of this thickness difference as well. In the present exemplary embodiment, the controller 320 constitutes a calculator of the present disclosure.

In the present exemplary embodiment, though the feed-forward control is performed for the rough grinding of the next wafer W, the feed-forward control may be performed for the medium grinding of the current wafer W which is performed after the rough grinding of the current wafer W. For example, the feed-forward control may be performed for the medium grinding, which is a next process for the current wafer W, based on data upon the completion of the rough grinding of the current wafer W and data upon completion of medium grinding of a wafer W which is ground previously (hereinafter, referred to as “previous wafer W”). To elaborate, a wafer top surface height upon the completion of the rough grinding of the current wafer W is calculated, and a whetstone bottom surface height upon the completion of the medium grinding of the previous wafer W is calculated. Then, a feed-forward control for reducing an air cut amount in the subsequent medium grinding of the current wafer W may be performed based on these data.

According to the present exemplary embodiment, the reference position where the rough grinding wheel 280 is distanced away is measured for the current wafer W being ground currently, and the grinding start position of the rough grinding wheel 280 is calculated for the next wafer W to be ground subsequently by adding the edge cut amount and the target grinding amount of the wafer W to the reference position. In such a case, even if the rough grinding whetstone 281 is worn away, the edge cut amount can be regulated constant or minimized. Therefore, the processing time of the grinding can be shortened, and the throughput can be improved. Since the descending speed of the rough grinding wheel 280 in the edge cut is low, minimizing the edge cut amount is advantageous to improve the throughput.

Further, in the present exemplary embodiment, the reference position is measured based on the point where the loads acting on the chuck 200 and the rough grinding wheel 280 become zero. Here, the height of the rear surface of the wafer W measured by the laser displacement meter 430 may be used as a reference for the calculation of the reference position. However, the spark-out lasts from the time T5 to the time T6 and the escape cut lasts from the time T6 to the time T7 as described above, and the rear surface of the wafer W is slightly ground in these periods. Thus, the reference position cannot be accurately calculated from the measurement result of the laser displacement meter 430. Furthermore, since the laser displacement meter 430 measures a height of the wafer W at a single point, the reference position may not be calculated accurately if the height of the wafer W is not uniform within a surface thereof. According to the present exemplary embodiment, however, since the reference position is calculated based on the load zero point, it is possible to calculate the reference position accurately.

In addition, in the present exemplary embodiment, the point where both the load acting on the chuck 200 measured by the first load sensor 420 and the load acting on the rough grinding wheel 280 measured by the second load sensor 421 become zero is set as the load zero point, a point where either one of the load acting on the chuck 200 and the load acting on the rough grinding wheel 280 becomes zero may be set as the load zero point. For example, if it is assume that the chuck 200, for example, is not distorted at all, the load acting on the rough grinding wheel 280 measured by the second load sensor 421 may be used as a reference. In such a case, the first load sensor 420 may be omitted. Meanwhile, if it is assumed that the rough grinding wheel 280, for example, is not distorted at all, the load acting on the chuck 200 measured by the first load sensor 420 may be used as a reference. In such a case, the second load sensor 421 may be omitted.

So far, the exemplary embodiments of the present disclosure have been described. However, the present disclosure is not limited to the exemplary embodiments and it would be understood by those skilled in the art that various changes and modifications may be made without departing from the scope of the present disclosure as claimed in the claims and all these changes and modifications are included in the scope of the present disclosure.

Though the above-described exemplary embodiments have been described for the wafer W having the front surface to which the protective tape is attached, the present disclosure is also applicable to a wafer W, such as a support wafer or a glass substrate, to which a support board is attached.

### EXPLANATION OF CODES

1: Substrate processing system
30: Grinding apparatus
31: Cleaning apparatus
40: Turntable
50: Transfer unit
60: Alignment unit
70: Cleaning unit
80: Rough grinding unit
90: Medium grinding unit
100: Fine grinding unit
200: Chuck
280: Rough grinding wheel
281: Rough grinding whetstone
285: Driver
290: Medium grinding wheel
291: Medium grinding whetstone
295: Driver
300: Fine grinding wheel
301: Fine grinding whetstone
305: Driver
320: Controller
400: Polishing unit
410: Detection unit
411: Inspection unit
420, 421: load sensor
W: Wafer

We claim:

1. A grinding apparatus configured to grind a substrate, comprising:
a substrate holder configured to hold the substrate; and
an annular grinder configured to come into contact with at least a central portion and a peripheral portion of the substrate held by the substrate holder to grind the substrate,
wherein the substrate holder includes multiple substrate holders and the grinder includes multiple grinders, and
a diameter of at least one of the multiple grinders is different from a diameter of others of the multiple grinders.

2. The grinding apparatus of claim 1,
wherein the multiple grinders include a rough grinder configured to roughly grind the substrate and a fine grinder configured to finely grind the substrate roughly ground, and
a diameter of the fine grinder is larger than a diameter of the rough grinder.

3. The grinding apparatus of claim 2,
wherein the multiple grinders further include a medium grinder configured to grind the substrate at a medium level before the substrate is finely ground and after the substrate is roughly ground, and
a diameter of the medium grinder is equal to the diameter of the rough grinder.

4. The grinding apparatus of claim 1, further comprising:
a detector configured to detect a grinding mark formed on the substrate after the substrate is ground by the multiple grinders; and
an inspector configured to inspect states of the multiple grinders based on the grinding mark detected by the detector.

5. The grinding apparatus of claim 1, further comprising:
a load measurer configured to measure a load acting on the substrate holder or the grinder at least;
a height measurer configured to measure a height position of the grinder when the load measured by the load measurer becomes zero after the substrate is ground by the grinder; and
a calculator configured to calculate a grinding start position of a substrate to be subsequently ground by a grinder based on the height position of the grinder measured by the height measurer.

6. The grinding apparatus of claim 5,
wherein the load measurer includes two load measurers, and the two load measurers are provided at two places,
a first load measurer of the two load measurers is configured to measure the load acting on the substrate holder, and
a second load measurer of the two load measurers is configured to measure the load acting on the grinder.

7. A grinding method of grinding a substrate, comprising:
multiple grinding processes of grinding the substrate by bringing an annular grinder into contact with at least a central portion and a peripheral portion of the substrate held by a substrate holder,
wherein the grinder includes multiple grinders, and a diameter of at least one of the multiple grinders used in the multiple grinding processes is different from a diameter of others of the multiple grinders.

8. The grinding method of claim 7,
wherein the multiple grinding processes include a rough grinding process of roughly grinding the substrate by using a rough grinder in the multiple grinders and a fine grinding process of finely grinding the substrate by using a fine grinder in the multiple grinders, and
a diameter of the fine grinder is larger than a diameter of the rough grinder.

9. The grinding method of claim 8,
wherein the multiple grinding processes include a medium grinding process of grinding the substrate at a medium level by using a medium grinder in the multiple grinders before the substrate is finely ground and after the substrate is roughly ground, and
a diameter of the medium grinder is equal to the diameter of the rough grinder.

10. The grinding method of claim 7, further comprising:
a detection process of detecting a grinding mark formed on the substrate after the multiple grinding processes; and
an inspection process of inspecting a state of the multiple grinders based on the grinding mark detected in the detection process.

11. The grinding method of claim 7,
wherein the grinding processes comprise:
a load measuring process of measuring a load acting on the substrate holder or the grinder at least when grinding the substrate by the grinder;
a height measuring process of measuring a height position of the grinder when the load measured in the load measuring process becomes zero after the substrate is ground by the grinder; and
a calculating process of calculating, based on the height position of the grinder measured in the height measuring process, a grinding start position of a substrate to be subsequently ground by the grinder.

12. The grinding method of claim 11,
wherein both the load acting on the substrate holder and the load acting on the grinder are measured in the load measuring process.

13. A computer-readable recording medium having stored thereon computer-executable instructions that, in response to execution, cause a grinding apparatus to perform a grinding method of grinding a substrate,
wherein the grinding method comprises:
multiple grinding processes of grinding the substrate by bringing an annular grinder into contact with at least a central portion and a peripheral portion of the substrate held by a substrate holder, and
the grinder includes multiple grinders, and a diameter of at least one of the multiple grinders used in the multiple grinding processes is different from a diameter of others of the multiple grinders.
